(19) United States
(12) Patent Application Publication
(10) Pub. No.: US 2021/0223990 A1
(43) Pub. Date: Jul. 22, 2021

(54) SEMICONDUCTOR MEMORY DEVICE, CONTROLLER, AND STORAGE DEVICE HAVING SEMICONDUCTOR MEMORY DEVICE AND CONTROLLER

(71) Applicant: SK hynix Inc., Icheon-si Gyeonggi-do (KR)

(72) Inventor: Ki Cheol SON, Icheon-si Gyeonggi-do (KR)

(73) Assignee: SK hynix Inc., Icheon-si Gyeonggi-do (KR)

(21) Appl. No.: 16/929,877

(22) Filed: Jul. 15, 2020

(30) Foreign Application Priority Data
Jan. 21, 2020 (KR) 10-2020-0008086

(51) Int. Cl. G06F 3/06

(52) U.S. Cl. CPC G06F 3/0659; G06F 3/0679; G06F 3/0604

(57) ABSTRACT

Provided herein may be a semiconductor memory device, a controller, and a storage device having the same. The storage device may include a semiconductor memory device and a controller. The semiconductor memory device includes a first physical page that is coupled to a first word line and a second physical page that is coupled to a second word line. The controller controls a read operation of the semiconductor memory device. Identical data is stored in each of the first physical page and in the second physical page. The semiconductor memory device reads the data by randomly selecting any one of the first physical page and the second physical page.

### CROSS-REFERENCE TO RELATED APPLICATION

The present application claims priority under 35 U.S.C. § 119(a) to Korean patent application number 10-2020-0008086, filed on Jan. 21, 2020, in the Korean Intellectual Property Office, the entire disclosure of which is incorporated herein by reference.

### BACKGROUND

### 1. Technical Field

Various embodiments of the present disclosure relate to an electronic device, and more particularly, to a semiconductor memory device, a controller, and a storage device having the semiconductor memory device and the controller.

### 2. Related Art

A memory device may have a two-dimensional (2D) structure in which strings are horizontally arranged on a semiconductor substrate. Alternatively, the memory device may have a three-dimensional (3D) structure in which strings are vertically stacked on a semiconductor substrate. As the memory device with a 2D structure is reaching its physical scaling limit (i.e., limit in the degree of integration), semiconductor manufacturers are producing 3D memory devices that include a plurality of memory cells that are vertically stacked on a semiconductor substrate. Meanwhile, a controller may control the operation of a semiconductor memory device in response to a request received from a host.

### SUMMARY

An embodiment of the present disclosure may provide for a storage device. The storage device may include a semiconductor memory device and a controller. The semiconductor memory device includes a first physical page that is coupled to a first word line and a second physical page that is coupled to a second word line. The controller controls a read operation of the semiconductor memory device. Here, identical data is stored in each of the first physical page and in the second physical page. The semiconductor memory device reads the data by randomly selecting any one of the first physical page and the second physical page.

An embodiment of the present disclosure may provide for a storage device. The storage device may include a semiconductor memory device and a controller. The semiconductor memory device includes a plurality of page group, and the page group includes a plurality of physical pages. The controller controls a read operation of the semiconductor memory device. Here, identical data is stored in each of the plurality of physical pages in the page group. The semiconductor memory device may read the data by randomly selecting any one of the plurality of physical pages.

An embodiment of the present disclosure may provide for a method of operating a controller, by which a read operation of a semiconductor memory device in which identical page data is stored in each of a plurality of physical pages is controlled. The method may include determining to read the page data that is stored in each of the plurality of physical pages, randomly generating a read address that corresponds to any one of the plurality of physical pages in response to the determination, generating a read command based on the generated read address, and transferring the generated read address and read command to the semiconductor memory device.

An embodiment of the present disclosure may provide for a method of operating a semiconductor memory device, the semiconductor memory device including a plurality of physical pages, each in which identical page data is stored. The method may include receiving a read command for reading the page data, randomly selecting any one of the plurality of physical pages in response to reception of the read command, and performing a read operation on the selected physical page.

### BRIEF DESCRIPTION OF THE DRAWINGS

FIG. 1 is a block diagram, illustrating a storage device with a controller, according to an embodiment of the present disclosure.

FIG. 2 is a block diagram, illustrating a semiconductor memory device, according to an embodiment of the present disclosure.

FIG. 3 is a diagram, illustrating an embodiment of a memory cell array of FIG. 2.

FIG. 4 is a circuit diagram, illustrating any one memory block BLKa of memory blocks BLK1 to BLKz of FIG. 3.

FIG. 5 is a circuit diagram, illustrating an example of any one memory block BLKb of the memory blocks BLK1 to BLKz of FIG. 3.

FIG. 6 is a circuit diagram, illustrating an example of any one memory block BLKc of the memory blocks BLK1 to BLKz, included in the memory cell array 110 of FIG. 2.

FIG. 7 is a diagram explaining data, stored in a memory block of a semiconductor memory device, according to an embodiment of the present disclosure.

FIG. 8 is a diagram, illustrating a read operation of a semiconductor memory device, according to an embodiment of the present disclosure.

FIG. 9 is a circuit diagram, illustrating an example of a page group.

FIG. 10 is a circuit diagram, illustrating an example of a memory block, including a plurality of page groups.

FIG. 11 is a flowchart, illustrating a method of operating a semiconductor memory device, according to an embodiment of the present disclosure.

FIG. 12 is a flowchart, illustrating an exemplary embodiment of a multi-page program operation.

FIG. 13 is a flowchart, illustrating an embodiment of a multi-page program operation.

FIG. 14 is a block diagram, illustrating a controller 200, according to an embodiment of the present disclosure.

FIG. 15 is a block diagram, illustrating a semiconductor memory device 100, according to an embodiment of the present disclosure.

FIG. 16 is a flowchart, illustrating a method of operating the controller 200, according to an embodiment of the present disclosure.

FIG. 17 is a flowchart, illustrating a method of operating the semiconductor memory device 100, according to an embodiment of the present disclosure.

FIGS. 18A, 18B, 18C, and 18D are diagrams, illustrating examples in which a CAM read operation is repeatedly performed, according to an embodiment of the present disclosure.

FIG. 19 is a block diagram, illustrating a storage device with a semiconductor memory device, according to an embodiment of the present disclosure.

FIG. 20 is a block diagram, illustrating a controller, according to an embodiment of the present disclosure,

FIG. 21 is a block diagram, illustrating a semiconductor memory device 100′, according to an embodiment of the present disclosure.

FIG. 22 is a block diagram, illustrating an exemplary embodiment of a random address generator 101, illustrated in illustrated in FIG. 21.

FIG. 23 is a flowchart, illustrating a method of operating a controller 200′, according to an embodiment of the present disclosure.

FIG. 24 is a flowchart, illustrating a method of operating the semiconductor memory device 100′, according to an embodiment of the present disclosure.

FIG. 25 is a block diagram, illustrating an example of the controller of FIG. 1.

FIG. 26 is a block diagram, illustrating an example 2000 of application of the storage device of FIG. 25.

FIG. 27 is a block diagram, illustrating a computing system including the storage device, described with reference to FIG. 26.

### DETAILED DESCRIPTION

Specific structural or functional descriptions in the embodiments of the present disclosure introduced in this specification or application are exemplified to describe embodiments according to the concept of the present disclosure. The embodiments according to the concept of the present disclosure may be practiced in various forms, and should not be construed as being limited to the embodiments described in the specification or application.

Various embodiments of the present disclosure are directed to a semiconductor memory device with improved reliability and a controller to control the semiconductor memory device.

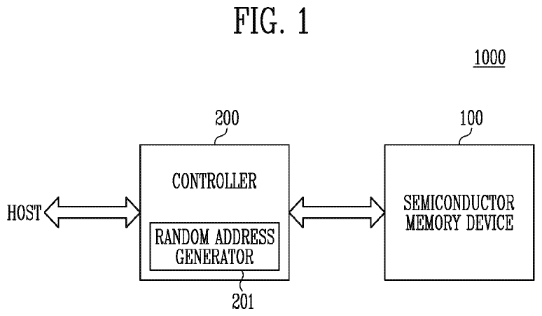

FIG. 1 is a block diagram, illustrating a storage device including a controller; according to an embodiment of the present disclosure.

Referring to FIG. 1, a storage device 1000 may include a semiconductor memory device 100 and a controller 200. Further, the storage device 1000 communicates with a host. The controller 200 controls the overall operation of the semiconductor memory device 100. Also, the controller 200 controls the operation of the semiconductor memory device 100 in response to a command that is received from the host.

The semiconductor memory device 100 is operated based on the controller 200. The semiconductor memory device 100 may include a memory cell array with a plurality of memory blocks. In an embodiment, the semiconductor memory device 100 may be a flash memory device.

The controller 200 may receive a data write request, a data read request, or an erase request from the host, and the controller 200 may control the semiconductor memory device 100 in response to the received request. In detail, the controller 200 may generate commands to control the operation of the semiconductor memory device 100 and may transmit the commands to the semiconductor memory device 100.

The semiconductor memory device 100 may receive a command and an address from the controller 200 and may access the area of the memory cell array that is selected by the address. That is, the semiconductor memory device 100 may perform an internal operation that corresponds to the command on the area that is selected by the address.

For example, the semiconductor memory device 100 may perform a program operation, a read operation, and an erase operation. During a program operation, the semiconductor memory device 100 may program data to the area that is selected by the address. During a read operation, the semiconductor memory device 100 may read data from the area that is selected by the address. During an erase operation, the semiconductor memory device 100 may erase data that is stored in the area that is selected by the address.

The semiconductor memory device 100 may include a content-addressable memory (CAM) area, that is, a CAM area. The CAM area may include at least one CAM block. In an embodiment, at least one of the plurality of memory blocks that are included in the semiconductor memory device 100 may be defined as a CAM block that stores data related to option parameters for the semiconductor memory device 100, and data related to initially set read voltage indices, and data related to a read retry table. The remaining memory blocks may be defined as normal memory blocks.

When transferring a read command for the CAM area to the semiconductor memory device 100, the controller 200 also transfers an address of a physical page that is the target of a read operation to the semiconductor memory device 100. In this case, the address of the physical page that is the target of the read operation may be determined to be an address, corresponding to a physical address that is randomly selected from at least two physical pages in which the same page data is stored in common.

For this operation, the controller 200 may include a random address generator 201. The random address generator 201 may randomly select the physical page that is the target of the read operation and may generate an address that corresponds to the physical page. Therefore, when the CAM read operation is repeatedly performed, read operations on a plurality of physical pages may be uniformly performed. This may mitigate the degradation of threshold voltage characteristics of memory cells in the physical page that is attributable to the repeated read operation. Therefore, the reliability of the CAM read operation may be improved.

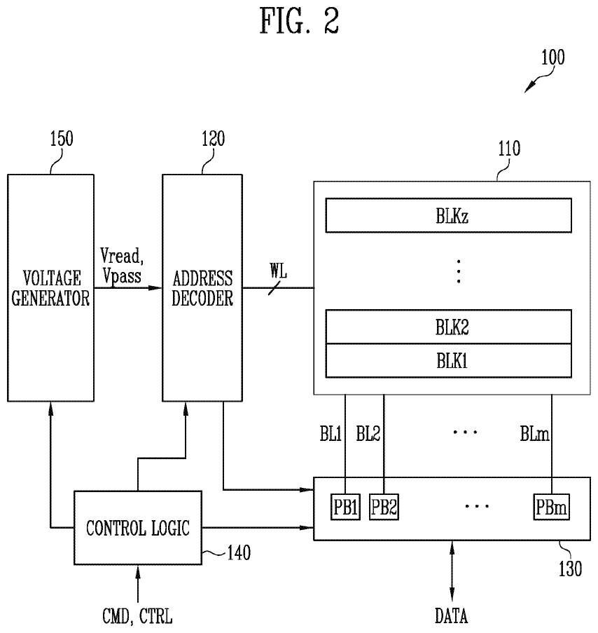

FIG. 2 is a block diagram, illustrating a semiconductor memory device, according to an embodiment of the present disclosure.

Referring to FIG. 2, the semiconductor memory device 100 may include a memory cell array 110, an address decoder 120, a read and write circuit 130, a control logic 140, and a voltage generator 150.

The memory cell array 110 may include a plurality of memory blocks BLK1 to BLKz. The memory blocks BLK1 to BLKz may be coupled to the address decoder 120 through word lines WL. The memory blocks BLK1 to BLKz may be coupled to the read and write circuit 130 through bit lines BL1 to BLm. Each of the memory blocks BLK1 to BLKz may include a plurality of memory cells. In an embodiment, the plurality of memory cells may be nonvolatile memory cells and may be implemented as nonvolatile memory cells with a vertical channel structure. The memory cell array 110 may be implemented as a memory cell array with a two-dimensional (2D) structure. In an embodiment, the memory cell array 110 may be implemented as a memory cell array with a three-dimensional (3D) structure. Each of the memory cells that are included in the memory cell array may store at least one bit of data. In an embodiment, each of the memory cells that are included in the memory cell array 110 may be a single-level cell (SLC), which stores 1-bit data. In an embodiment, each of the memory cells that are included in the memory cell array 110 may be a multi-level cell (MLC), which stores 2-bit data. In an embodiment, each of the memory cells that are included in the memory cell array 110 may be a triple-level cell (TLC), which stores 3-bit data. In an embodiment, each of the memory cells that are included in the memory cell array 110 may be a quad-level cell (QLC), which stores 4-bit data. In various embodiments, the memory cell array 110 may include a plurality of memory cells, each of which stores 5 or more bits of data.

In an embodiment of the present disclosure, at least one of the plurality of memory blocks BLK1 to BLKz may be defined as a content-addressable memory (CAM) block that stores data related to option parameters for the semiconductor memory device 100, data related to initially set read voltage indices, and data related to a read retry table. The remaining memory blocks BLK1 to BLKz-1 may be defined as normal memory blocks.

The CAM block and the normal memory blocks may have the same structure. In detail, conditions that are set in relation to a data input/output operation or other pieces of information may be stored in the CAM block. In an embodiment, the number of read/write operations (i.e., the number of program/erase (P/E) cycles), bad column address information, and bad block address information may be stored in the CAM block. In an embodiment, option information that is required to operate the semiconductor memory device 100 (for example, program voltage information, read voltage information, erase voltage information, or information related to the thickness of a gate oxide layer of a cell) may be stored in the CAM block. In an embodiment, repair information may be stored in the CAM block. When power is supplied to the semiconductor memory device 100, the pieces of information that are stored in the CAM block may be read by a peripheral circuit, and the peripheral circuit may control the memory cell array so that a data input/output operation is performed on the memory cells in the set conditions based on the read information.

The address decoder 120, the read and write circuit 130, the control logic 140, and the voltage generator 150 are operated as peripheral circuits for driving the memory cell array 110. The address decoder 120 is coupled to the memory cell array 110 through the word lines WL. The address decoder 120 may be operated based on the control logic 140. The address decoder 120 may receive addresses through an input/output buffer (not illustrated) that is provided in the semiconductor memory device 100. When power is supplied to the semiconductor memory device 100, the pieces of information that are stored in the CAM block may be read by a peripheral circuit, and the peripheral circuit may control the memory cell array so that a data input/output operation is performed on the memory cells in the set conditions based on the read information.

The address decoder 120 may decode a block address, among the received addresses. The address decoder 120 selects at least one memory block based on the decoded block address. When a read voltage application operation is performed during a read operation, the address decoder 120 may apply a read voltage Vread, generated by the voltage generator 150, to a selected word line of a selected memory block, and the address decoder 120 may apply a pass voltage Vpass to remaining unselected word lines. During a program verify operation, the address decoder 120 may apply a verify voltage, generated by the voltage generator 150, to a selected word line of a selected memory block, and the address decoder 120 may apply the pass voltage Vpass to remaining unselected word lines.

The address decoder 120 may decode a column address, among the received addresses. The address decoder 120 may transmit the decoded column address to the read and write circuit 130.

The read and program operations of the semiconductor memory device 100 may be each performed on a page basis. Addresses that are received at the request of read and program operations may include a block address, a row address, and a column address. The address decoder 120 may select one memory block and one word line in accordance with the block address and the row address. The column address may be decoded by the address decoder 120, and the column address may then be provided to the read and write circuit 130. In the present specification, memory cells that are coupled to one word line may be referred to as a “physical page.”

The address decoder 120 may include a block decoder, a row decoder, a column decoder, an address buffer, etc.

The read and write circuit 130 may include a plurality of page buffers PB1 to PBm. The read and write circuit 130 may be operated as a “read circuit” during a read operation of the memory cell array 110 and as a “write circuit” during a write operation thereof. The plurality of page buffers PB1 to PBm may be coupled to the memory cell array 110 through the bit lines BL1 to BLm. During a read or program verify operation, in order to sense threshold voltages of the memory cells, the page buffers PB1 to PBm may continuously supply a sensing current to the bit lines that are coupled to the memory cells while each of the page buffers PB1 to PBm senses, through a sensing node, a change in the amount of flowing current based on the program state of a corresponding memory cell and latches it as sensing data. The read and write circuit 130 may be operated in response to page buffer control signals outputted from the control logic 140.

During a read operation, the read and write circuit 130 may sense data that is stored in the memory cells, may temporarily store read data, and then may output data DATA to the input/output buffer (not illustrated) of the semiconductor memory device 100. In an embodiment, the read and write circuit 130 may include a column select circuit or the like as well as the page buffers (or page resistors).

The control logic 140 may be coupled to the address decoder 120, the read and write circuit 130, and the voltage generator 150. The control logic 140 may receive a command CMD and a control signal CTRL through the input/output buffer (not illustrated) of the semiconductor memory device 100. The control logic 140 may control the overall operation of the semiconductor memory device 100 in response to the control signal CTRL. The control logic 140 may output a control signal to control a precharge potential level at the sensing node of the plurality of page buffers PB1 to PBm. The control logic 140 may control the read and write circuit 130 to perform a read operation of the memory cell array 110.

The voltage generator 150 may generate a read voltage Vread and a pass voltage Vpass required for a read operation in response to a control signal outputted from the control logic 140. The voltage generator 150 may include a plurality of pumping capacitors for receiving an internal supply voltage to generate a plurality of voltages with various voltage levels, and may generate a plurality of voltages by selectively enabling the plurality of pumping capacitors based on the control logic 140.

The address decoder 120, the read and write circuit 130, and the voltage generator 150 may function as “peripheral circuits” which perform a read operation, a write operation, and an erase operation on the memory cell array 110. The peripheral circuits may perform a read operation, a write operation, and an erase operation on the memory cell array 110 based on the control logic 140.

The above-described option information related to the operation of the semiconductor memory device 100 may be stored in the CAM block of the semiconductor memory device 100. In the above-described option information, one piece of page data may be equally stored in first and second physical pages. That is, the first physical page and the second physical page may store the same page data. In an embodiment, the above-described option information may be equally stored in three or more physical pages. In this way, when the option information or the like is stored in the CAM area, one piece of page data may be equally stored in at least two physical pages. The reason for this is that, when adjacent physical pages store different pieces of data, the reliability of data may be deteriorated.

In typical cases, when the controller 200 requires the option information stored in the CAM area, the controller 200 may transfer a CAM read command to the semiconductor memory device 100. In this case, the controller 200 does not transfer the address of a physical page in which the option information is actually stored to the semiconductor memory device 100. Typically, the semiconductor memory device 100 has information related to the address of the CAM area, so that when the CAM read command is received, the semiconductor memory device 100 may read data that is stored in the CAM area, corresponding to the CAM read command, and transfer the read data to the controller 200. An operation of reading the data in the CAM area may be referred to as a “CAM read operation”. When the read operation is performed on the data equally stored in the at least two physical pages included in the CAM area, a read operation may be performed on one preset physical page. Even if the CAM read operation is repeatedly performed, the read operation on the one preset physical page is performed. Since the CAM read operation is repeatedly performed on the one preset physical page, among the plurality of physical pages which store the same data, the threshold voltage characteristics of memory cells included in the corresponding physical page may be degraded. This may lead to a decrease in reliability for the CAM read operation.

When transferring a read command for the CAM area to the semiconductor memory device 100, the controller 200 according to the embodiment of the present disclosure also transfers an address of a physical page that is the target of a read operation to the semiconductor memory device 100. In this case, the address of the physical page that is the target of the read operation may be determined to be an address corresponding to a physical address randomly selected from at least two physical pages in which the same page data is stored in common.

The semiconductor memory device 100 may receive a read command and an address for the CAM area. Meanwhile, the semiconductor memory device 100 may read the data of the physical page corresponding to the received address, and may transfer the read data to the controller 200. Since the address received from the controller 200 is an address corresponding to the physical page randomly selected from among a plurality of physical pages in the CAM area, the physical page that is the target of an actual read operation may also be randomly determined whenever the CAM read operation is repeatedly performed. Therefore, when the CAM read operation is repeatedly performed, read operations on the plurality of physical pages in the CAM area may be uniformly performed. This may mitigate the degradation of threshold voltage characteristics of memory cells in the physical page attributable to the repeated read operation. Therefore, the reliability of the CAM read operation may be improved.

The semiconductor memory device 100 according to an embodiment of the present disclosure receives only a read command for a CAM area from the controller 200. Meanwhile, the semiconductor memory device 100 may perform a read operation on the physical page randomly selected from among the plurality of physical pages in the CAM area in response to the received read command. For this operation, when the read command for the CAM area is received, the semiconductor memory device 100 may randomly select any one from among the addresses respectively corresponding to the plurality of physical pages in the CAM area. Also, the semiconductor memory device 100 may read the data of the physical page that corresponds to the randomly selected address, and may transfer the data to the controller 200. Accordingly, whenever the CAM read operation is repeatedly performed, the physical page that is the target of the actual read operation may also be randomly determined. Consequently, when the CAM read operation is repeatedly performed, read operations on the plurality of physical pages in the CAM area may be uniformly performed. This may mitigate the degradation of threshold voltage characteristics of memory cells in the physical page that is attributable to the repeated read operation. Therefore, the reliability of the CAM read operation may be improved.

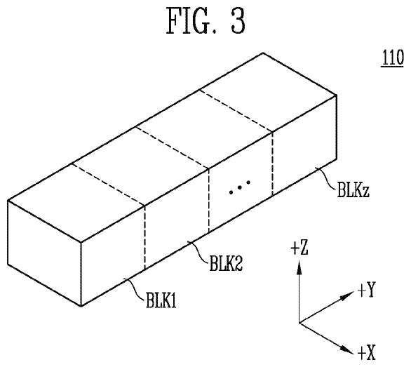

FIG. 3 is a diagram, illustrating an embodiment of the memory cell array of FIG. 2.

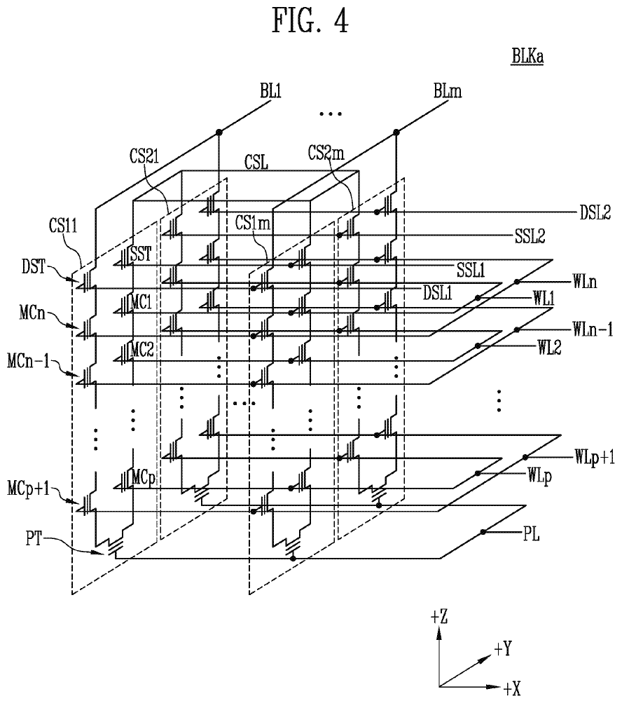

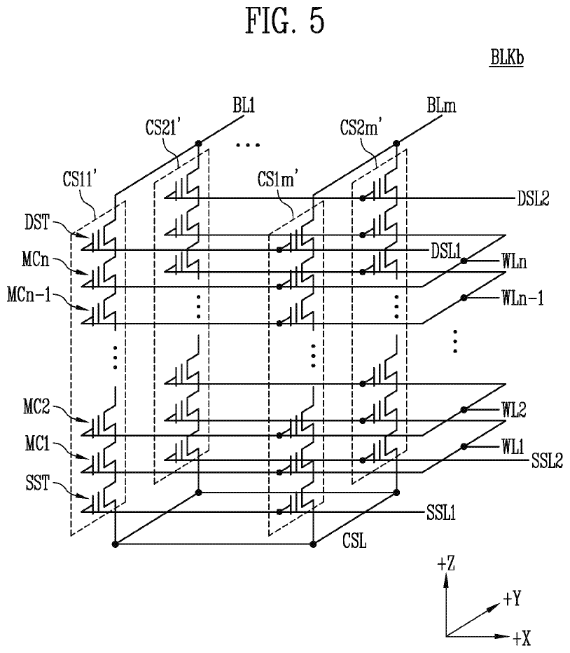

Referring to FIG. 3, the memory cell array 110 may include a plurality of memory blocks BLK1 to BLKz. Each memory block may have a three-dimensional (3D) structure. Each memory block may include a plurality of memory cells that are stacked on a substrate. Such memory cells may be arranged along a positive X (+X) direction, a positive Y (+Y) direction, and a positive Z (+Z) direction. The structure of each memory block will be described in detail below with reference to FIGS. 4 and 5.

FIG. 4 is a circuit diagram, illustrating any one memory block BLKa of the memory blocks BLK1 to BLKz of FIG. 3.

Referring to FIG. 4, the memory block BLKa may include a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings may be arranged in a row direction (i.e. a positive (+) X direction). In FIG. 4, two cell strings may be illustrated as being arranged in a column direction (i.e. a positive (+) Y direction). However, this illustration is made for convenience of description, and it will be understood that three or more cell strings may be arranged in the column direction.

Each of the plurality of cell strings CS11 to CS1m and CS21 to CS2m may include at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided to each cell string. In an embodiment, a pillar for providing at least one of the channel layer, the tunneling insulating layer, the charge storage layer, and the blocking insulating layer may be provided to each cell string.

The source select transistor SST of each cell string may be connected between the common source line CSL and memory cells MC1 to MCp.

In an embodiment, the source select transistors of cell strings that are arranged in the same row may be coupled to a source select line extended in a row direction, and source select transistors of cell strings arranged in different rows may be coupled to different source select lines. In FIG. 4, source select transistors of cell strings CS11 to CS1m in a first row may be coupled to a first source select line SSL1. The source select transistors of cell strings CS21 to CS2m in a second row may be coupled to a second source select line SSL2.

In an embodiment, source select transistors of the cell strings CS11 to CS1m and CS21 to CS2m may be coupled in common to a single source select line.

The first to nth memory cells MC1 to MCn in each cell string may be coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp may be sequentially arranged in a direction opposite a positive (+) Z direction and may be connected, in series, between the source select transistor SST and the pipe transistor PT. The p+1-th to n-th memory cells MCp+1 to MCn may be sequentially arranged in the +Z direction and may be connected, in series, between the pipe transistor PT and the drain select transistor DST. The first to p-th memory cells MC1 to MCp and the p+1-th to n-th memory cells MCp+1 to MCn may be coupled to each other through the pipe transistor PT. The gates of the first to n-th memory cells MC1 to MCn of each cell string may be coupled to first to n-th word lines WL1 to WLn, respectively.

The gate of the pipe transistor PT of each cell string may be coupled to a pipeline PL.

The drain select transistor DST of each cell string may be connected between the corresponding bit line and the memory cells MCp+1 to MCn. The cell strings in a row direction may be coupled to drain select lines that are extended in a row direction. Drain select transistors of cell strings CS11 to CS1m in the first row may be coupled to a first drain select line DSL1. Drain select transistors of cell strings CS21 to CS2m in a second row may be coupled to a second drain select line DSL2.

Cell strings that are arranged in a column direction may be coupled to bit lines extended in a column direction. In FIG. 4, cell strings CS11 and CS21 in a first column may be coupled to a first bit line BL1. Cell strings CS1m and CS2m in an m-th column may be coupled to an m-th bit line BLm.

The memory cells, coupled to the same word line in cell strings, arranged in a row direction, may constitute a single page. For example, memory cells that are coupled to the first word line WL1, among the cell strings CS11 to CS1m in the first row, may constitute a single page. Memory cells that are coupled to the first word line WL1, among the cell strings CS21 to CS2m in the second row, may constitute a single additional page. Cell strings that are arranged in the direction of a single row may be selected by selecting any one of the drain select lines DSL1 and DSL2. A single page may be selected from the selected cell strings by selecting any one of the word lines WL1 to WLn.

In an embodiment, even bit lines and odd bit lines, instead of first to m-th bit lines BL1 to BLm, may be provided. Further, even-numbered cell strings, among the cell strings CS11 to CS1m or CS21 to CS2m arranged in a row direction, may be coupled to the even bit lines, respectively, and odd-numbered cell strings, among the cell strings CS11 to CS1m or CS21 to CS2m arranged in the row direction, may be coupled to the odd bit lines, respectively.

In an embodiment, one or more of the first to n-th memory cells MC1 to MCn may be used as dummy memory cells. For example, one or more dummy memory cells may be provided to reduce an electric field between the source select transistor SST and the memory cells MC1 to MCp. Alternatively, the one or more dummy memory cells may be provided to reduce an electric field between the drain select transistor DST and the memory cells MCp+1 to MCn. As more dummy memory cells are provided, the reliability of the operation of the memory block BLKa may be improved. However, the size of the memory block BLKa increases. As fewer memory cells are provided, the size of the memory block BLKa is reduced. In this case, the reliability of the operation of the memory block BLKa may deteriorate.

In order to efficiently control the one or more dummy memory cells, each of the dummy memory cells may have a required threshold voltage. Before or after the erase operation of the memory block BLKa is performed, a program operation may be performed on all or some of the dummy memory cells. When an erase operation is performed after the program operation has been performed, the threshold voltages of the dummy memory cells may control the voltages that are applied to the dummy word lines, coupled to respective dummy memory cells, and thus, the dummy memory cells may have required threshold voltages.

FIG. 5 is a circuit diagram, illustrating an example of any one memory block BLKb of the memory blocks BLK1 to BLKz of FIG. 3.

Referring to FIG. 5, the memory block BLKb may include a plurality of cell strings CS11′ to CS1m′ and CS21′ to CS2m′. Each of the plurality of cell strings CS11′ to CS1m′ and CS21′ to CS2m′ may be extended along a positive Z (+Z) direction. Each of the cell strings CS11′ to CS1m′ and CS21′ to CS2m′ may include at least one source select transistor SST, first to n-th memory cells MC1 to MCn, and at least one drain select transistor DST, which are stacked on a substrate (not illustrated) below the memory block BLKb.

The source select transistor SST of each cell string may be connected between a common source line CSL and memory cells MC1 to MCn. The source select transistors of cell strings that are arranged in the same row may be coupled to the same source select line. Source select transistors of cell strings CS11′ to CS1m′ that are arranged in a first row may be coupled to a first source select line SSL1. Source select transistors of cell strings CS21′ to CS2m′ that are arranged in a second row may be coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string may be connected, in series, between the source select transistor SST and the drain select transistor DST. The gates of the first to n-th memory cells MC1 to MCn may be coupled to first to n-th word lines WL1 to WLn, respectively.

The drain select transistor DST of each cell string may be connected between the corresponding bit line and the memory cells MC1 to MCn. Drain select transistors of cell strings that are arranged in a row direction may be coupled to drain select lines extended in a row direction. The drain select transistors of the cell strings CS11′ to CS1m′ in the first row may be coupled to a first drain select line DSL1. The drain select transistors of the cell strings CS21′ to CS2m′ in the second row may be coupled to a second drain select line DSL2.

As a result, the memory block BLKb of FIG. 5 may have an equivalent circuit that is similar to that of the memory block BLKa of FIG. 4, except that a pipe transistor PT may be excluded from each cell string.

In an embodiment, even bit lines and odd bit lines, instead of first to m-th bit lines BL1 to BLm, may be provided. Further, even-numbered cell strings, among the cell strings CS11′ to CS1m′ or CS21′ to CS2m′ arranged in a row direction, may be coupled to the even bit lines, respectively, and odd-numbered cell strings, among the cell strings CS11′ to CS1m′ or CS21′ to CS2m′ arranged in the row direction, may be coupled to the odd bit lines, respectively.

In an embodiment, one or more of the first to n-th memory cells MC1 to MCn may be used as dummy memory cells. For example, the one or more dummy memory cells may be provided to reduce an electric field between the source select transistor SST and the memory cells MC1 to MCn. Alternatively, the one or more dummy memory cells may be provided to reduce an electric field between the drain select transistor DST and the memory cells MC1 to MCn. As more dummy memory cells are provided, the reliability of the operation of the memory block BLKb may be improved. However, the size of the memory block BLKb increases. As fewer memory cells are provided, the size of the memory block BLKb is reduced. However, the reliability of the operation of the memory block BLKb may deteriorate.

In order to efficiently control the one or more dummy memory cells, each of the dummy memory cells may have a required threshold voltage. Before or after the erase operation of the memory block BLKb is performed, a program operation may be performed on all or some of the dummy memory cells. When an erase operation is performed after the program operation has been performed, the threshold voltages of the dummy memory cells may control the voltages that are applied to the dummy word lines, coupled to respective dummy memory cells, and thus, the dummy memory cells may have required threshold voltages.

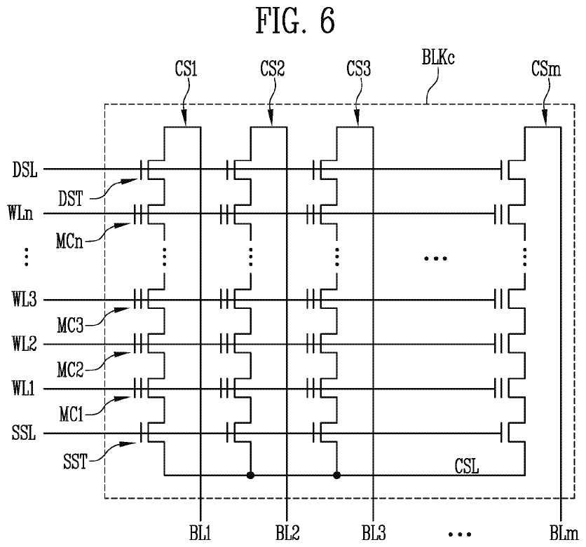

FIG. 6 is a circuit diagram, illustrating an example of any one memory block BLKc of the memory blocks BLK1 to BLKz, included in the memory cell array 110 of FIG. 2.

Referring to FIG. 6, the memory block BLKc may include a plurality of cell strings CS1 to CSm. The plurality of cell strings CS1 to CSm may be coupled to a plurality of bit lines BL1 to BLm, respectively. Each of the cell strings CS1 to CSm may include at least one source select transistor SST, first to n-th memory cells MC1 to MCn, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string may be coupled between a common source line CSL and the memory cells MC1 to MCn.

The first to n-th memory cells MC1 to MCn in each cell string may be coupled between the source select transistor SST and the drain select transistor DST.

The drain select transistor DST of each cell string may be coupled between the corresponding bit line and the memory cells MC1 to MCn.

The memory cells that are coupled to the same word line may constitute a single page. The cell strings CS1 to CSm may be selected by selecting the drain select line DSL. One page may be selected from the selected cell strings by selecting any one of the word lines WL1 to WLn.

In other embodiments, even bit lines and odd bit lines may be provided instead of the first to m-th bit lines BL1 to BLm. Among the cell strings CS1 to CSm, even-numbered cell strings may be coupled to the even bit lines, respectively, and odd-numbered cell strings may be coupled to the odd bit lines, respectively.

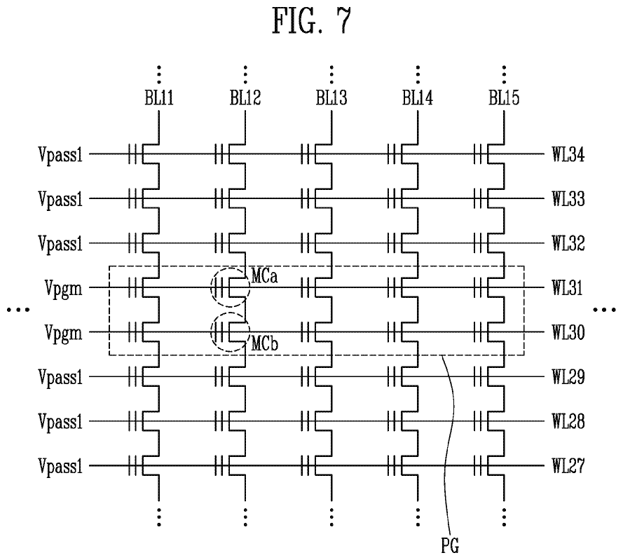

FIG. 7 is a diagram, explaining data that is stored in a memory block of a semiconductor memory device, according to an embodiment of the present disclosure. Referring to FIG. 7, part of a memory block BLK is illustrated. The memory block BLK of FIG. 7 may be a CAM block. More specifically, memory cells that are defined by 27-th to 34-th word lines WL27 to WL34 and eleventh to fifteenth bit lines BL11 to BL15 of the memory block BLK may be illustrated.

At least one of the memory blocks BLK1 to BLKz of the semiconductor memory device 100 may include a page group PG. The page group PG may include at least two physical pages. In an example of FIG. 7, the page group PG may include a physical page (first page) corresponding to a 30-th word line WL30 and a physical page (second page) corresponding to a 31-st word line WL31. In the first page and the second page, the same data may be stored. In other words, a plurality of physical pages, belonging to one page group PG, may store the same data.

In an embodiment, in order to store the same data in the first and second pages belonging to the page group PG, the 30-th word line WL30 and the 31-st word line WL31 may be simultaneously selected during a program operation.

A program pass voltage Vpass1 may be applied to the remaining word lines WL27 to WL29 and WL32 to WL34 that are not selected. Meanwhile, a program voltage Vpgm may be simultaneously applied to the selected word lines WL30 and WL31. Accordingly, the same data may be stored in the first and second physical pages, respectively corresponding to the selected word lines WL30 and WL31.

In the above description, the method of storing the same data in the first and second physical pages by simultaneously applying a program pulse to the 30-th and 31-st word lines WL30 and WL31 has been described. However, in other embodiments, the first physical page corresponding to the 30-th word line WL30 may be first programmed, and the second physical page corresponding to the 31-st word line WL31 may be subsequently programmed. In this way, the same data may be programmed to the first and second physical pages.

As the same data is programmed to the first and second pages belonging to the page group PG, the threshold voltages of memory cells MCa and MCb may be included in the same program state P1.

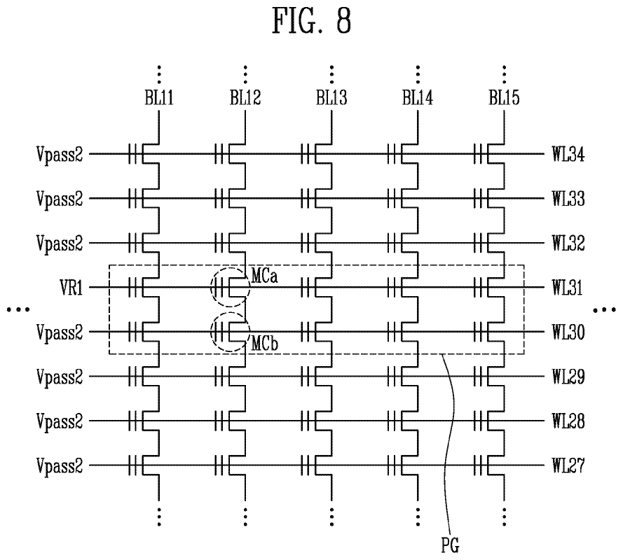

Thereafter, a CAM read operation of reading data that is stored in the page group PG may be performed. The CAM read operation will be described below with reference to FIG. 8.

FIG. 8 is a diagram, illustrating a read operation of a semiconductor memory device, according to an embodiment of the present disclosure. Referring to FIG. 8, an example of the operation of reading data included in the page group PG is illustrated.

In typical cases, the semiconductor memory device 100 may receive a read command for the page group PG from the controller 200. In this case, a detailed address of the physical page that is the target on which the read operation is to be performed is not received. The semiconductor memory device 100 may perform a read operation on a physical page coupled to a preset 31-st word line WL31. That is, the physical page coupled to the 31-st word line WL31 may be a physical page preset as the detailed target of a read operation during the operation of reading data that is stored in the page group PG.

The control logic 140 may control the voltage generator 150 and the address decoder 120 so that a read voltage VR1 may be applied to the 31-st word line WL31 in response to the read command for the page group PG. Meanwhile, the control logic 140 may control the voltage generator 150 and the address decoder 120 so that a read pass voltage Vpass2 is applied to other word lines.

As described above, in typical cases, when it is desired to read data that is stored in a CAM area, for example, the page group PG, the controller 200 may transfer a CAM read command to the semiconductor memory device. The semiconductor memory device may read data from a physical page corresponding to the preset address, for example, a physical page coupled to the 31-st word line WL31 in response to the received CAM read command. When the CAM read operation is repeatedly performed, data in the physical page that is coupled to the 31-st word line WL31 between the two physical pages in the page group PG is repeatedly read. Since the CAM read operation is repeatedly performed on the one preset physical page, among the plurality of physical pages which store the same data, the threshold voltage characteristics of memory cells that are included in the corresponding physical page may be degraded. This may lead to a decrease in reliability for the CAM read operation.

When transferring a read command for the CAM area to the semiconductor memory device 100, the controller 200 may also transfer an address of a physical page that is the target of a read operation to the semiconductor memory device 100. In this case, the address of the physical page that is the target of the read operation may be determined to be an address corresponding to a physical address randomly selected from at least two physical pages in which the same page data is stored in common. That is, a read operation may be performed on any one physical page that is randomly selected between the physical page coupled to the 30-th word line WL30 and the physical page coupled to the 31-st word line WL31, Therefore, when the CAM read operation is repeatedly performed, read operations on a plurality of physical pages in the page group PG may be uniformly performed. This may mitigate the degradation of threshold voltage characteristics of memory cells in the physical page attributable to the repeated read operation. Therefore, the reliability of the CAM read operation may be improved.

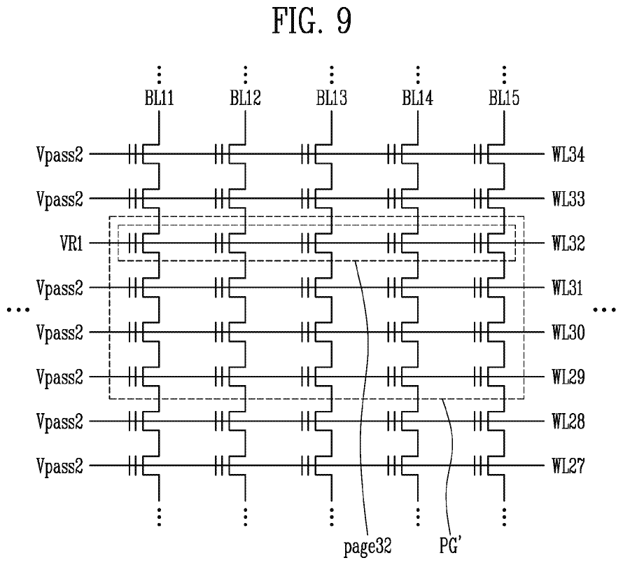

FIG. 9 is a circuit diagram, illustrating an example of a page group, Referring to FIGS. 7 and 8, the page group PG is illustrated as including two physical pages that correspond to 30-th and 31-st word lines WL30 and WL31. However, an embodiment of the present disclosure is not limited thereto, and one page group may include a variety of numbers of physical pages. As illustrated in FIG. 11, a page group PG′, according to an embodiment of the present disclosure, may also include four physical pages that correspond to word lines WL29 to WL32. Meanwhile, in accordance with an embodiment of the present disclosure, one page group may include five or more physical pages.

Even in this case, the semiconductor memory device may typically read data from a physical page that corresponds to the preset address (for example, a 32-nd physical page page32 coupled to the 32-nd word line WL32 in response to a received CAM read command). When the CAM read operation is repeatedly performed, data in the 32-nd physical page page32, among the four physical pages in the page group PG, may be repeatedly read. Since the CAM read operation is repeatedly performed on the one preset physical page, among the plurality of physical pages which store the same data, the threshold voltage characteristics of memory cells that are included in the corresponding physical page may be degraded. This may lead to a decrease in reliability for the CAM read operation.

When transferring a read command for the CAM area to the semiconductor memory device 100, the controller 200 also may transfer an address of a physical page that is the target of a read operation to the semiconductor memory device 100. In this case, the address of the physical page that is the target of the read operation may be determined to be an address that corresponds to a physical address randomly selected from at least two physical pages in which the same page data is stored in common. That is, a read operation is performed on any one physical page, randomly selected from among the physical pages, coupled to the 29-th to 31-st word lines WL29 to WL31. Therefore, when the CAM read operation is repeatedly performed, read operations on a plurality of physical pages in the page group PG may be uniformly performed. This may mitigate the degradation of threshold voltage characteristics of memory cells in the physical page that are attributable to the repeated read operation. Therefore, the reliability of the CAM read operation may be improved.

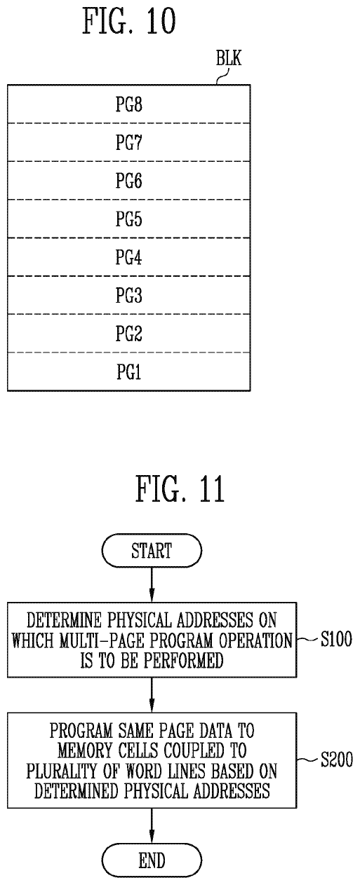

FIG. 10 is a circuit diagram, illustrating an example of a memory block including a plurality of page groups. Referring to FIG. 10, physical pages in a memory block BLK may be divided into eight page groups PG1 to PG8. However, the configuration of FIG. 10 is merely exemplary, and a variety of numbers of page groups may be defined. For example, the memory block BLK may include only two page groups. In an embodiment, one memory block may form one page group. In this case, during a multi-page read operation that is performed on the page group, a read voltage VR1 may be applied to all word lines that are coupled to the memory block, and thus, a read operation may be performed.

Meanwhile, in FIG. 10, the entire memory block BLK is illustrated as forming page groups PG1 to PG8. However, the semiconductor memory device 100 is not limited thereto. For example, only a partial area of one memory block BLK may form page groups. In this case, the remaining area, which does not form page groups, may configure normal physical pages.

FIG. 11 is a flowchart, illustrating a method of operating a semiconductor memory device, according to an embodiment of the present disclosure.

Referring to FIG. 11, the method of operating the semiconductor memory device may include step S100 of determining physical addresses on which a multi-page program operation is to be performed and step S200 of programming the same page data to memory cells that are coupled to a plurality of word lines based on the determined physical addresses. Hereinafter, a description will be made with reference to FIG. 7 together with FIG. 11.

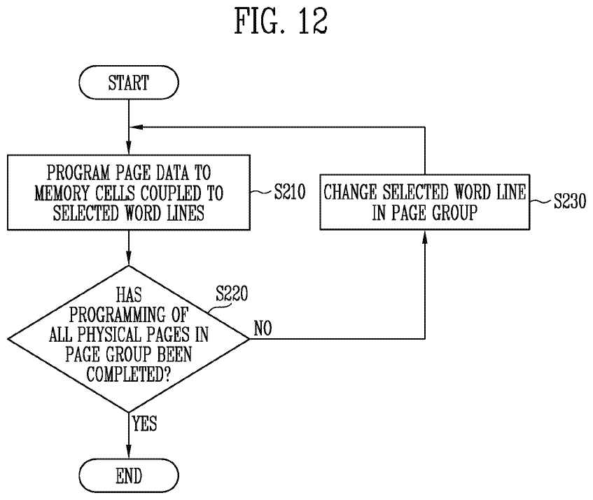

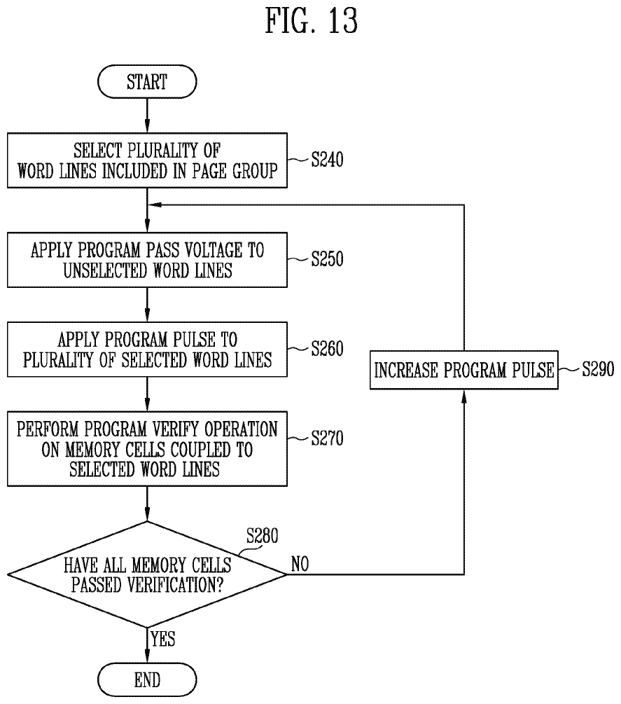

At step S100, the physical addresses on which the multi-page program operation is to be performed may be determined. For example, as illustrated in FIG. 7, physical addresses that correspond to word lines WL30 and WL31 may be determined. Thereafter, at step S200, the same page data may be programmed to the physical pages that correspond to the selected word lines WL30 and WL31. That is, the multi-page program operation may be performed on the determined physical addresses at step S200. Detailed embodiments of step S200 will be described in detail below with reference to FIGS. 12 and 13.

FIG. 12 is a flowchart, illustrating an exemplary embodiment of a multi-page program operation. That is, an exemplary embodiment of step S200 of FIG. 11 is illustrated in FIG. 12.

First, page data may be programmed to memory cells that are coupled to a selected word line at step S210. For example, first data may be programmed to a physical page that corresponds to a 30-th word line WL30. Step S210 may include a plurality of program loops and verify loops. The plurality of program loops that are included in step S210 may be performed based on an Incremental Step Pulse Programming (ISPP) method.

Thereafter, it may be determined whether programming of all physical pages in the page group PG has been completed at step S220. Since a physical page that corresponds to a 31-st word line WL31 is not yet programmed, the process proceeds to step S230.

At step S230, the selected word line in the page group PG may change. Since the programming of the physical page that corresponds to the 30-th word line has been completed, the selected word line may change to the 31-st word line WL31. Thereafter, the process may return to step S210 where the first data is programmed to the physical page that corresponds to the 31-st word line WL31.

Accordingly, the same first data may be programmed to the physical pages that corresponds to the 30-th and 31-st word lines WL30 and WL31. Since the programming of all physical pages in the page group PG has been completed as a result of the determination at step S220, the multi-page program operation on the corresponding page group PG may be completed.

FIG. 13 is a flowchart, illustrating an exemplary embodiment of a multi-page program operation. That is, an exemplary embodiment of step S200 of FIG. 11 is illustrated in FIG. 13. Hereinafter, a description will be made with reference to FIG. 7 together with FIG. 13.

At step S240, a plurality of word lines that are included in a page group may be selected. As illustrated in FIG. 7, 30-th and 31-st word lines WL30 and WL31 that are included in the page group PG may be selected.

At step S250, a program pass voltage may be applied to unselected word lines. As illustrated in FIG. 7, a program pass voltage Vpass1 may be applied to unselected word lines WL27 to WL29 and WL32 to WL34. It can be seen that the program pass voltage Vpass1 is applied to other unselected word lines that are not illustrated in FIG. 7.

At step S260, a program pulse may be applied to the plurality of selected word lines. As illustrated in FIG. 7, the threshold voltages of program target cells that belong to the page group PG may be increased by applying a program pulse Vpgm to the 30-th and 31-st word lines WL30 and WL31. For this operation, a program permission voltage may be applied to bit lines that are coupled to the program target cells. Further, in order to maintain the threshold voltages of memory cells that are not to be programmed, a program inhibition voltage may be applied to some of bit lines BL11 to BL15.

Thereafter, at step S270, a program verify operation, on memory cells that are coupled to the selected word lines WL30 and WL31, may be performed. For this operation, at step S270, a verify operation may be performed on the 30-th word line WL30, after which the verify operation may be performed on the 31-st word line WL31.

Thereafter, at step S280, whether all memory cells belonging to the page group PG have passed the verification may be determined. When all of the memory cells have passed the verification, the multi-page program may be terminated. In contrast, when all of the memory cells do not pass the verification, the process may proceed to step S290 where a program pulse increases. Thereafter, the process may return to step S250 where a subsequent program loop is performed.

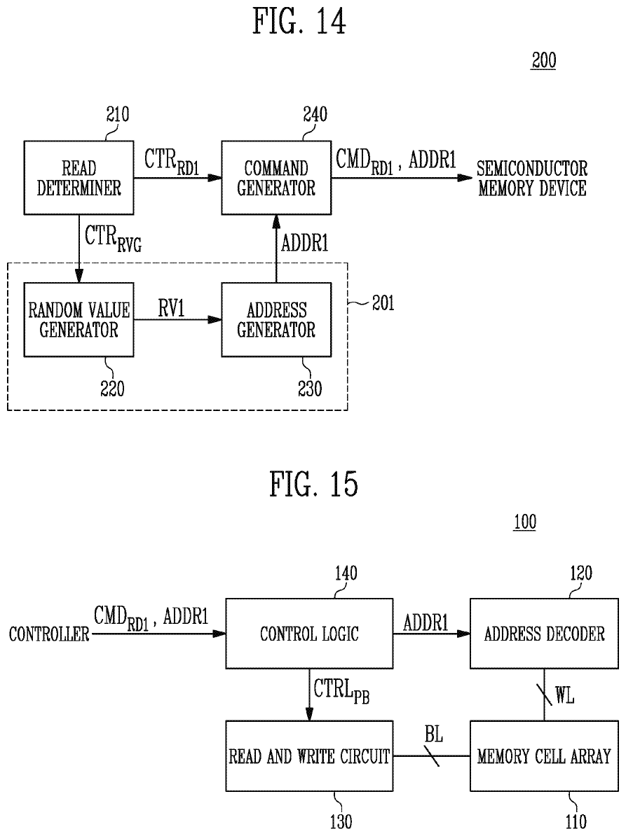

FIG. 14 is a block diagram, illustrating the controller 200, according to an embodiment of the present disclosure. Referring to FIG. 14, the controller 200 may include a read determiner 210, a random address generator 201, and a command generator 240. Meanwhile, the random address generator 201 may include a random value generator 220 and an address generator 230.

The read determiner 210 may determine to read data that is stored in a CAM area of a semiconductor memory device 100. When the controller 200 requires option data or the like that is stored in the CAM area, the read determiner 210 may determine to read the data that is stored in the CAM area, and the controller 200 may generate a read control signal CTR_{RD1} and a random value generation control signal CTR_{RVG}. The read control signal CTR_{RD1} may be transferred to the command generator 240, and the random value generation control signal CTR_{RVG} may be transferred to the random value generator 220.

The random address generator 201 may generate a random address ADDR1 in response to the random value generation control signal CTR_{RVG}. In detail, the random value generator 220 of the random address generator 201 may generate a random value RV1 in response to the received random value generation control signal CTR_{RVG}. The random value RV1 may be generated using a random seed or the like, and the random value RV1 may be generated in accordance with the number of physical pages that are included in a page group PG.

For example, as illustrated in FIGS. 7 and 8, when the page group PG includes two physical pages, the random value RV1 may be a value that is randomly selected from two different values. For example, as illustrated in FIG. 9, when the page group PG′ includes four physical pages, the random value RV1 may be a value that is randomly selected from among four different values.

The generated random value RV1 may be transferred to the address generator 230. The address generator 230 may generate the address ADDR1 based on the random value RV1. The address ADDR1 may be an address that corresponds to any one of the physical pages that are included in the page group PG.

For example, as illustrated in FIGS. 7 and 8, when the page group PG includes two physical pages, the address ADDR1 may be an address that corresponds to any one physical page, determined based on the random value RV1 that is between two physical pages respectively coupled to 30-th and 31-st word lines WL30 and WL31.

In an embodiment, as illustrated in FIG. 9, when the page group PG′ includes four physical pages, the address ADDR1 may be an address that corresponds to any one physical page, determined based on the random value RV1 from among four physical pages respectively coupled to 29-th to 32-nd word lines WL29 to WL32.

The generated address ADDR1 may be transferred to the command generator 240.

The command generator 240 may generate a read command CMD_{RD1} in response to the read control signal CTR_{RD1} and may transfer the read command CMD_{RD1} to the semiconductor memory device. Also, the command generator 240 may transfer the address ADDR1 that is received from the address generator 230, together with the read command CMD_{RD1}, to the semiconductor memory device.

FIG. 15 is a block diagram, illustrating the semiconductor memory device 100, according to an embodiment of the present disclosure.

Referring to FIG. 15, the semiconductor memory device 100 may include a memory cell array 110, an address decoder 120, a read and write circuit 130, and a control logic 140. The memory cell array 110, the address decoder 120, the read and write circuit 130, and the control logic 140 of FIG. 15 may be substantially the same as the memory cell array 110, the address decoder 120, the read and write circuit 130, and the control logic 140 of FIG. 2.

The control logic 140 may receive a read command CMD_{RD1} and an address ADDR1 from a controller. The received address ADDR1 may be transferred to the address decoder 120. The address decoder 120 may decode word lines WL in response to the received address ADDR1.

Meanwhile, the control logic 140 may generate a control signal CTRL_{PB} to control the read and write circuit 130 in response to the read command CMD_{RD1}. The read and write circuit 130 may read data that is stored in the memory cell array 110 through a bit line BL in response to the control signal CTRL_{PB}. Here, the data in physical pages that are coupled to the word lines, decoded by the address decoder 120, may be read. The read data may be transferred to the controller 200.

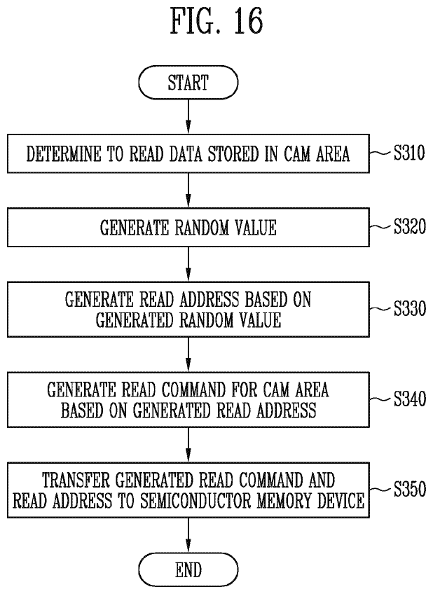

FIG. 16 is a flowchart, illustrating a method of operating the controller 200, according to an embodiment of the present disclosure.

Referring to FIG. 16, it may be determined to read data that is stored in a CAM area at step S310, and thus, a random value may be generated at step S320. Step S310 may be performed by the read determiner 210, and step S320 may be performed by the random value generator 220.

Thereafter, a read address may be generated based on the generated random value at step S330, and a read command for the CAM area may be generated based on the generated read address at step S340. Thereafter, the generated read command and read address may be transferred to the semiconductor memory device 100 at step S350. Step S330 may be performed by the address generator 230, and steps S340 and S350 may be performed by the command generator 240.

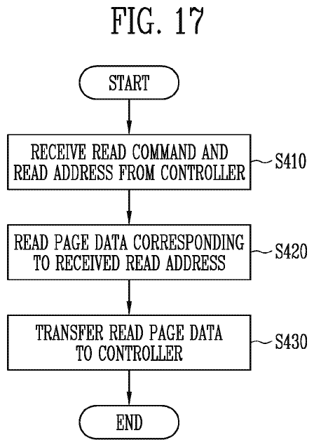

FIG. 17 is a flowchart, illustrating a method of operating the semiconductor memory device 100, according to an embodiment of the present disclosure. Referring to FIG. 17, a read command and a read address may be received from the controller at step S410, page data that corresponds to the received read address may be read at step S420, and the read page data may be transferred to the controller at step S430. Individual steps of FIG. 17 may be performed by the control logic 140, the read and write circuit 130, the address decoder 120, etc., described with reference to FIG. 15.

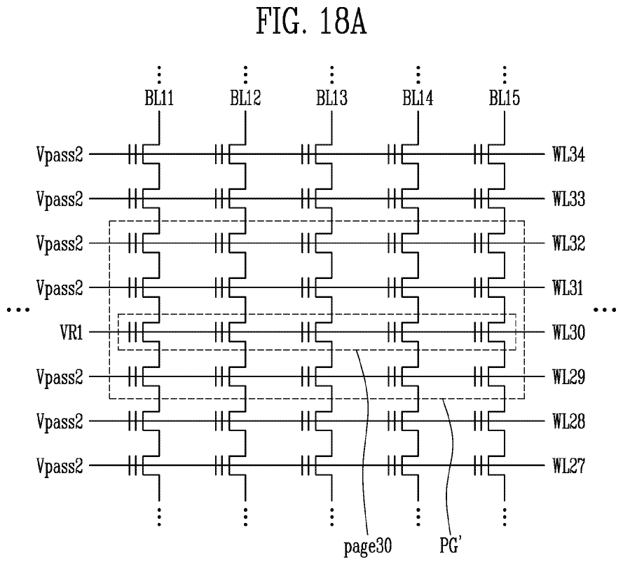

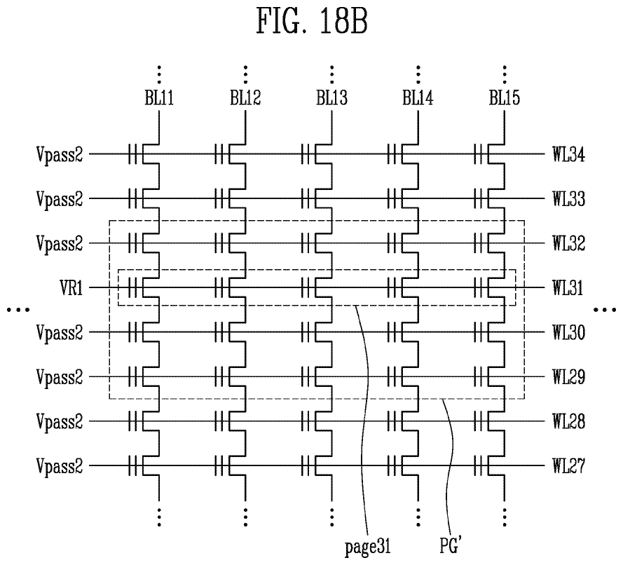

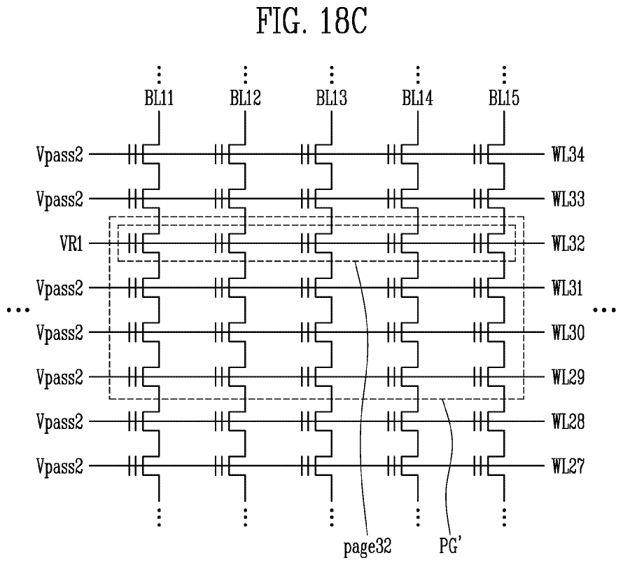

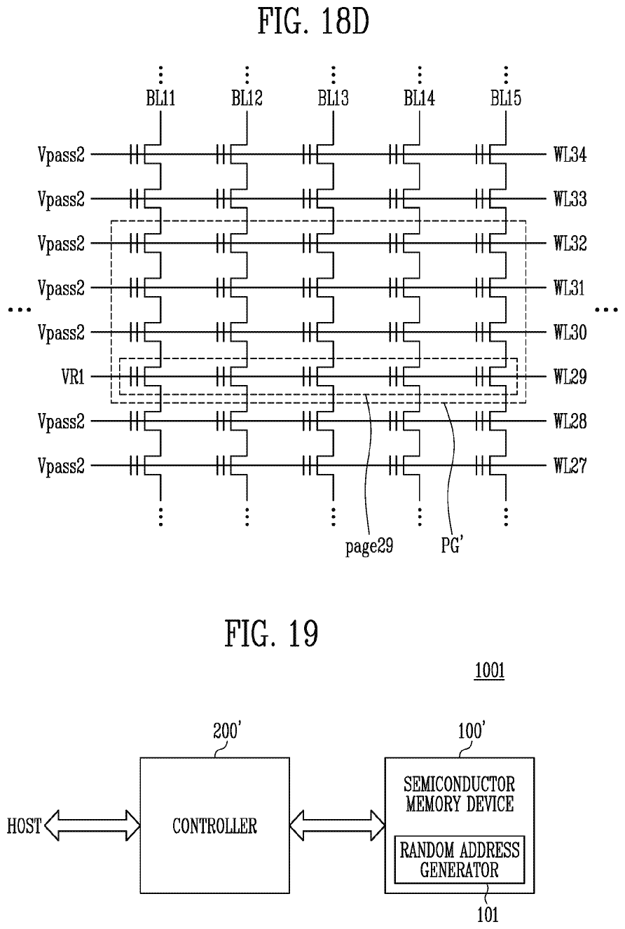

FIGS. 18A, 18B, 18C, and 18D are diagrams, illustrating examples in which a CAM read operation is repeatedly performed, according to an embodiment of the present disclosure. In detail, FIGS. 18A, 18B, 18C, and 18D are intended to exemplarily explain a CAM read operation on the page group PG′ of FIG. 9.

Referring to FIG. 18A, a 30-th page page30 may be selected by the random value generator 220 and the address generator 230 of FIG. 14, and an address ADDR1 corresponding to the 30-th page is generated. More specifically, the read determiner 210 may determine to read data that is stored in the CAM area, and the read determiner 210 may then generate a random value generation control signal CTR_{RVG} and transfer it to the random value generator 220. The read determiner 210 may also generate a read control signal CTR_{RD1} and may transfer the read control signal CTR_{RD1} to the command generator 240.

The random value generator 220 may generate a random value RV1 based on the random value generation control signal CTR_{RVG}. The random value RV1 may be a randomly generated value. That is, the random value RV1 may be a value that is randomly determined whenever it is generated by the random value generator 220. When the random value generator 220 repeatedly generates the random value RV1, the generated random values RV1 may have different values.

The address generator 230 may generate the address ADDR1 based on the random value RV1. The address ADDR1 may be an address that corresponds to any one of physical pages that are included in the page group PG.

The command generator 240 may generate a read command CMD_{RD1} in response to the received read control signal CTR_{RD1} and may transfer the read command to the semiconductor memory device. Also, the command generator 240 may transfer the address ADDR1 that is received from the address generator 230, together with the read command CMD_{RD1}, to the semiconductor memory device.

In FIG. 18A, a case where the random value RV1, generated by the random value generator 220, is a random value that corresponds to the 30-th word line WL30 is illustrated. In an example, the random value generator 220 may generate any one of values of 0 to 3 as the random value RV1. In an example, a random value RV1 of 0 may correspond to the 29-th word line WL29, and a random value RV1 of 1 may correspond to the 30-th word line WL30. Further, a random value RV1 of 2 may correspond to the 31-st word line WL31, and a random value RV1 of 3 may correspond to the 32-nd word line WL32.

In the example of FIG. 18A, an example in which a random value RV1 of 1 is generated and transferred to the address generator 230 and in which the address generator 230 generates the address ADDR1 that corresponds to the 30-th page page30 and transfers it to the command generator 240 is illustrated. Accordingly, the semiconductor memory device 100 may perform a read operation on the 30-th page page30.

In an example of FIG. 18B, a CAM read operation that is performed again on the page group PG′ after the read operation of FIG. 18A has been performed is illustrated.

In FIG. 18B, a case where the random value RV1, generated by the random value generator 220, is a random value that corresponds to the 31-st word line WL31 is illustrated. When the above-described example, together with the present example, is taken into consideration, the random value generator 220 may generate any one of values of 0 to 3 as the random value RV1. In an example, a random value RV1 of 0 may correspond to the 29-th word line WL29, and a random value RV1 of 1 may correspond to the 30-th word line WL30. Further, a random value RV1 of 2 may correspond to the 31-st word line WL31, and a random value RV1 of 3 may correspond to the 32-nd word line WL32. In the example of FIG. 18B, a random value RV1 of 2 may be generated and transferred to the address generator 230, and the address generator 230 may generate the address ADDR1 that corresponds to the 31-st page page31 and may transfer it to the command generator 240. Accordingly, the semiconductor memory device 100 may perform a read operation on the 31-st page page31.

In an example of FIG. 18C, a CAM read operation that is performed again on the page group PG′ after the read operation of FIG. 18B has been performed is illustrated.

In FIG. 18C, a case where the random value RV1, generated by the random value generator 220, is a random value that corresponds to the 32-nd word line WL32 is illustrated. When the above-described example, together with the present example, is taken into consideration, the random value generator 220 may generate any one of values of 0 to 3 as the random value RV1. In an example, a random value RV1 of 0 may correspond to the 29-th word line WL29, and a random value RV1 of 1 may correspond to the 30-th word line WL30. Further, a random value RV1 of 2 may correspond to the 31-st word line WL31, and a random value RV1 of 3 may correspond to the 32-nd word line WL32. In the example of FIG. 18C, a random value RV1 of 3 may be generated and transferred to the address generator 230, and the address generator 230 may generate the address ADDR1 that corresponds to the 32-nd page page32 and may transfer it to the command generator 240. Accordingly, the semiconductor memory device 100 may perform a read operation on the 32-nd page page32.

In an example of FIG. 18D, a CAM read operation that is performed again on the page group PG′ after the read operation of FIG. 18C has been performed is illustrated.

In FIG. 18D, a case where the random value RV1, generated by the random value generator 220, is a random value that corresponds to the 29-th word line WL29 is illustrated. When the above-described example, together with the present example, is taken into consideration, the random value generator 220 may generate any one of values of 0 to 3 as the random value RV1. In an example, a random value RV1 of 0 may correspond to the 29-th word line WL29, and a random value RV1 of 1 may correspond to the 30-th word line WL30. Further, a random value RV1 of 2 may correspond to the 31-st word line WL31, and a random value RV1 of 3 may correspond to the 32-nd word line WL32. In the example of FIG. 18D, a random value RV1 of 0 may be generated and transferred to the address generator 230, and the address generator 230 may generate the address ADDR1 that corresponds to the 29-th page page29 and may transfer it to the command generator 240. Accordingly, the semiconductor memory device 100 may perform a read operation on the 29-th page page29.

Whenever the read command for the CAM read operation is generated in this way, the address may also be randomly generated. Referring to FIGS. 18A, 18B, 18C, and 18D, it can be seen that read operations on the 30-th page page30, the 31-st page page31, the 32-nd page page32, and the 29-th page page29 may be randomly performed. The target of the CAM read operation that is performed at each step may be the page randomly selected from among the 29-th page page29 to the 32-nd page page32.

FIG. 19 is a block diagram, illustrating a storage device with a semiconductor memory device, according to an embodiment of the present disclosure.

Referring to FIG. 19, a storage device 1001 may include a semiconductor memory device 100′ and a controller 200′. Further, the storage device 1001 may communicate with a host. The controller 200′ may control the overall operation of the semiconductor memory device 100′. Also, the controller 200′ may control the operation of the semiconductor memory device 100′ in response to a command received from the host.

Unlike the storage device 1000 of FIG. 1, the controller 200′ of the storage device 1001, illustrated in FIG. 19, does not include a random address generator. Instead, the semiconductor memory device 100′ of the storage device 1001, illustrated in FIG. 19, may include a random address generator 101. In accordance with the semiconductor memory device 100′, when a read command for the CAM read operation is received from the controller 200′, an address ADDR2 indicating a physical page that is the target of the actual read operation may be randomly generated. For this operation, the random address generator 101 of the semiconductor memory device 100′ may randomly select a physical page that is the target of the read operation and may generate an address that corresponds to the selected physical page in response to the received read command.

Accordingly, whenever the read command for the CAM read operation is received, the page that is the target of the read operation corresponding to the read command may be randomly selected. Therefore, when the CAM read operation is repeatedly performed, read operations on a plurality of physical pages may be uniformly performed. This may mitigate the degradation of threshold voltage characteristics of memory cells in the physical page that are attributable to the repeated read operation. Therefore, the reliability of the CAM read operation may be improved.

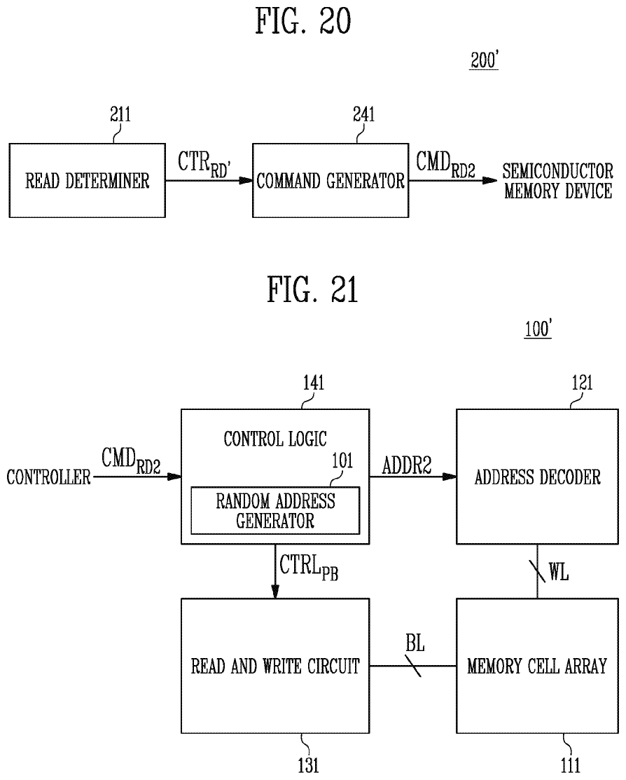

FIG. 20 is a block diagram, illustrating a controller, according to an embodiment of the present disclosure.

Referring to FIG. 20, a controller 200′ may include a read determiner 211 and a command generator 241.

The read determiner 211 may determine to read data that is stored in a CAM area of a semiconductor memory device 100′. When the controller 200′ requires option data or the like stored in the CAM area, the read determiner 211 may determine to read the data that is stored in the CAM area and may generate a read control signal CTR_{RD′}. The read control signal CTR_{RD′} may be transferred to the command generator 241.

The command generator 241 may generate a read command CMD_{RD2} in response to the read control signal CTR_{RD′} and may transfer the read command CMD_{RD2} to the semiconductor memory device. The read command CMD_{RD2} may be a command for reading data that is stored in a page group PG′.

When FIG. 20 is compared with FIG. 14, the controller 200′ of FIG. 20 does not include a random value generator and an address generator. That is, the controller 200′ of FIG. 20 may generate only the read command CMD_{RD2} for reading the data that is stored in the page group PG′ and may transfer it to the semiconductor memory device, without generating an address.

FIG. 21 is a block diagram, illustrating a semiconductor memory device 100′, according to an embodiment of the present disclosure.

Referring to FIG. 21, the semiconductor memory device 100′ may include a memory cell array 111, an address decoder 121, a read and write circuit 131, and a control logic 141. The memory cell array 111, the address decoder 121, and the read and write circuit 131 of FIG. 21 may be substantially the same as the memory cell array 110, the address decoder 120, and the read and write circuit 130 of FIG. 15.

The control logic 141 may receive a read command CMD_{RD2} from the controller. Meanwhile, the control logic 141 may generate an address ADDR2 that corresponds to the received read command CMD_{RD2}. In detail, the random address generator 101 that is included in the control logic 141 may generate the address ADDR2 that corresponds to the received read command CMD_{RD2}. The received address ADDR2 may be transferred to the address decoder 121. The address decoder 121 may decode word lines WL in response to the received address ADDR2.

Meanwhile, the control logic 141 may generate a read control signal CTRL_{PB} to control the read and write circuit 131 in response to the read command CMD_{RD2}. The read and write circuit 131 may read the data that is stored in the memory cell array 111 through a bit line BL in response to the read control signal CTRL_{PB}. Here, the data in physical pages that are coupled to word lines, decoded by the address decoder 121, may be read. The read data may be transferred to the controller 200′.

In accordance with the semiconductor memory device 100′, when the read command CMD_{RD2} for the CAM read operation is received, the address ADDR2 indicating a page that is the target of the actual read operation in the page group PG′ may be randomly generated. Accordingly, whenever the read command for the CAM read operation is received, the page that is the target of the read operation that corresponds to the read command is randomly selected.

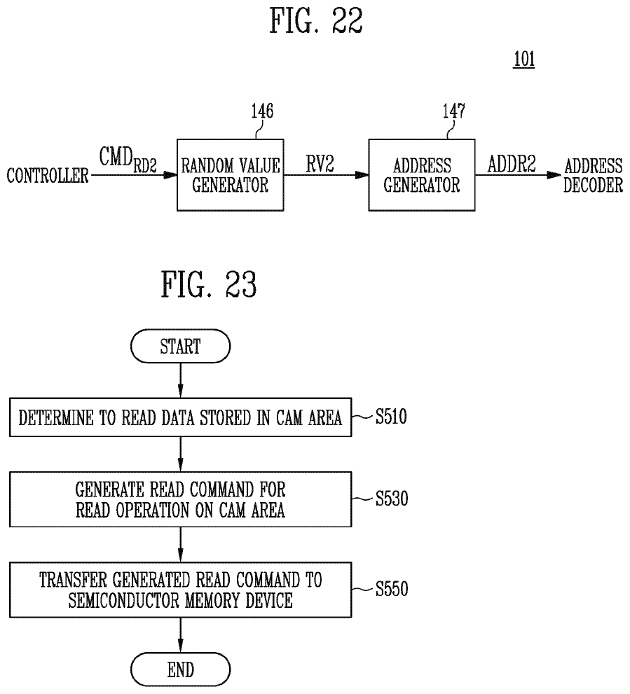

FIG. 22 is a block diagram, illustrating an exemplary embodiment of the random address generator 101 that is illustrated in FIG. 21.

Referring to FIG. 22, the random address generator 101 may include a random value generator 146 and an address generator 147.

The random value generator 146 may generate a random value RV2 in response to a read command CMD_{RD2} received from a controller.

The random value RV2 may be generated using a random seed or the like, and the random value RV2 may be generated in accordance with the number of physical pages included in a page group PG.

For example, as illustrated in FIGS. 7 and 8, when the page group PG includes two physical pages, the random value RV2 may be a value that is randomly selected from two different values. For example, as illustrated in FIG. 9, when the page group PG′ includes four physical pages, the random value RV2 may be a value that is randomly selected from among four different values.

The generated random value RV2 may be transferred to the address generator 147. The address generator 147 The random value RV2 an address ADDR2 based on the random value RV2. The address ADDR2 may be an address that corresponds to any one of physical pages that are included in the page group PG.

For example, as illustrated in FIGS. 7 and 8, when the page group PG includes two physical pages, the address ADDR2 may be an address that corresponds to any one physical page, determined based on the random value RV2, between two physical pages that are respectively coupled to 30-th and 31-st word lines WL30 and WL31.

In an embodiment, as illustrated in FIG. 9, when the page group PG′ includes four physical pages, the address ADDR2 may be an address that corresponds to any one physical page, determined based on the random value RV2, from among four physical pages that are respectively coupled to 29-th to 32-nd word lines WL29 to WL32.

The generated address ADDR2 may be transferred to the command generator 121.

FIG. 23 is a flowchart, illustrating a method of operating the controller 200′, according to an embodiment of the present disclosure. Referring to FIG. 23, the controller 200′ may determine to read data that is stored in a CAM area at step S510, and the controller 200′ may generate a read command CMD_{RD2} for performing a read operation on the CAM area based on the determination at step S530. Thereafter, the generated read command CMD_{RD2} may be transferred to the semiconductor memory device 100′ at step S550. Compared to the operating method of the controller 200 as illustrated in FIG. 16, the operating method of FIG. 23 may be performed such that the controller generates only the read command CMD_{RD2} and may transfer it to the semiconductor memory device 100′ without generating a read address on which a CAM read operation is to be performed through a random value.

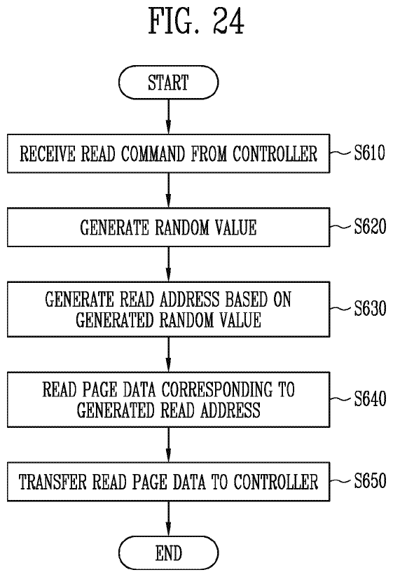

FIG. 24 is a flowchart, illustrating a method of operating the semiconductor memory device 100′, according to an embodiment of the present disclosure. Referring to FIG. 24, the random address generator 101 that is included in the control logic 141 of the semiconductor memory device 100′ may receive a read command CMD_{RD2} from the controller 200′ at step S610 and may generate a random value RV2 in response to the received read command CMD_{RD2} at step S620. Meanwhile, the random address generator 101 may generate a read address ADDR2 based on the generated random value RV2 at step S630, and the random address generator 101 may transfer the generated read address ADDR2 to the address decoder 121. The read and write circuit 131 may read page data that corresponds to the generated read address ADDR2 at step S640, and the read and write circuit 131 may transfer the read page data to the controller 200′ at step S650.

In accordance with the embodiments as illustrated in FIGS. 19 to 24, random selection of addresses may be performed in the semiconductor memory device 100′ rather than in the controller 200′.

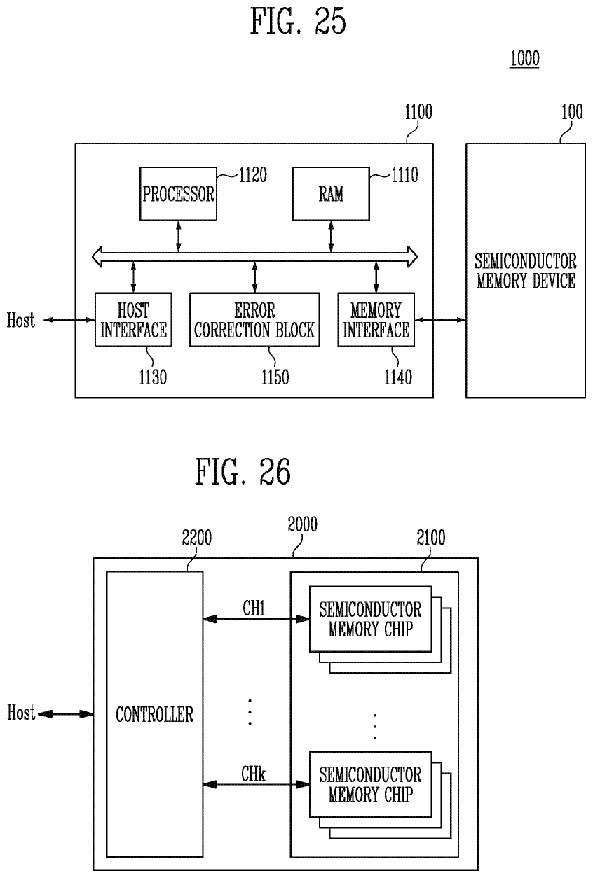

FIG. 25 is a block diagram, illustrating an example of the controller of FIG. 1.

Referring to FIG. 25, a storage device 1000 may include a semiconductor memory device 100 and a controller 1100.

The semiconductor memory device 100 of FIG. 25 may have the same configuration and operation as the semiconductor memory device 100 that is described with reference to FIG. 2. Hereinafter, repetitive explanations will be omitted.

The controller 1100 may be coupled to a host Host and the semiconductor memory device 100. The controller 1100 may access the semiconductor memory device 100 in response to a request from the host Host. For example, the controller 1100 may control read, program, erase, and background operations of the semiconductor memory device 100. The controller 1100 may provide an interface between the semiconductor memory device 100 and the host Host. The controller 1100 may run firmware to control the semiconductor memory device 100.

The controller 1100 may include a random access memory (RAM) 1110, a processor 1120, a host interface 1230, a memory interface 1240, and an error correction block 1150.

The RAM 1110 may be used as any one of a working memory for the processor 1120, a cache memory between the semiconductor memory device 100 and the host, and a buffer memory between the semiconductor memory device 100 and the host.

The processor 1120 may control the overall operation of the controller 1100. The processor 1120 may control read, program, erase, and background operations of the semiconductor memory device 100. The controller 1120 may run firmware to control the semiconductor memory device 100. The processor 1120 may perform a function of a flash translation layer (FTL). The processor 1120 may translate a logical block address (LBA), provided by the host, into a physical block address (PBA) through the FTL. The FTL may receive the LBA using a mapping table and translate the LBA into the PBA. Examples of an address mapping method performed through the FTL may include various methods according to a mapping unit. Representative address mapping methods include a page mapping method, a block mapping method, and a hybrid mapping method.

The processor 1120 may randomize data received from the host Host. For example, the processor 1120 may use a randomizing seed to randomize data received from the host Host. The randomized data is provided, as data to be stored, to the semiconductor memory device 100 and is then programmed to the memory cell array.

The processor 1120 may derandomize data received from the semiconductor memory device 100 during a read operation. For example, the processor 1120 may use a derandomizing seed to derandomize data received from the semiconductor memory device 100. Derandomized data may be output to the host Host.

In an embodiment, the processor 1120 may perform the randomizing and derandomizing operations by running software or firmware.

The read determiner 210, the random value generator 220, the address generator 230, and the command generator 240 of FIG. 14 may be implemented as firmware that is executed by the processor 1120 of FIG. 25. Also, the read determiner 211 and the command generator 241 of FIG. 19 may also be implemented as firmware that is executed by the processor 1120 of FIG. 25.

The host interface 1130 may include a protocol for performing data exchange between the host Host and the controller 1100. In an embodiment, the controller 1100 may communicate with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1140 may interface with the semiconductor memory device 100. For example, the memory interface 1140 may include a NAND interface or a NOR interface.

The error correction block 1150 may detect and correct errors in data received from the semiconductor memory device 100 using an error correction code (ECC). The error correction block 1150 may correct errors in read page data using an ECC. The error correction block 1150 may correct errors using a low density parity check (LDPC) code, a Bose, Chaudhri, Hocquenghem (BCH) Code, a turbo code, a Reed-Solomon code, a convolution code, a recursive systematic code (RSC), or coded modulation such as trellis-coded modulation (TCM), block coded modulation (BCM) or hamming code.

During a read operation, the error correction block 1150 may correct errors from read page data. When a number of error bits exceeding the number of correctable bits are included in the read page data, decoding may fail. When a number of error bits less than or equal to the number of correctable bits are included in the page data, decoding may succeed. A success in decoding indicates that the corresponding read command has passed. A failure in decoding indicates that the corresponding read command has failed. When decoding succeeds, the controller 1100 may output error-corrected page data to the host.

The controller 1100 and the semiconductor memory device 100 may be integrated into a single semiconductor device. In an embodiment, the controller 1100 and the semiconductor memory device 100 may be integrated into a single semiconductor device to form a memory card. For example, the controller 1100 and the semiconductor memory device 100 may be integrated into a single semiconductor device and form a memory card such as a personal computer memory card international association (PCMCIA), a compact flash card (CF), a smart media card (SMC), a memory stick multimedia card (MMC, RS-MMC, or MMCmicro), a SD card (SD, miniSD, microSD, or SDHC), or a universal flash storage (UFS).

The controller 1100 and the semiconductor memory device 100 may be integrated into a single semiconductor device to form a solid state drive (SSD). The SSD may include a storage device configured to store data in a semiconductor memory. When the storage device is used as the SSD, an operation speed of the host Host coupled to the storage device may be remarkably improved.

In an embodiment, the storage device 1000 may be provided as one of various elements of an electronic device such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional (3D) television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, or one of various elements for forming a computing system.

In an embodiment, the semiconductor memory device 100 or the storage device 1000 may be mounted in various types of packages. For example, the semiconductor memory device 100 or the storage device 1000 may be packaged and mounted in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), or Wafer-Level Processed Stack Package (WSP).

FIG. 26 is a block diagram, illustrating an example 2000 of application of the storage device of FIG. 25.

Referring to FIG. 26, a storage device 2000 may include a semiconductor memory device 2100 and a controller 2200. The semiconductor memory device 2100 may include a plurality of semiconductor memory chips. The semiconductor memory chips may be divided into a plurality of groups.

FIG. 26 illustrates a plurality of groups respectively communicating with the controller 2200 through first to k-th channels CH1 to CHk. Each semiconductor memory chip may have the same configuration and operation as the semiconductor memory device 100 described with reference to FIG. 25.

Each group may communicate with the controller 2200 through one common channel. The controller 2200 may have the same configuration as that of the controller 200 or 200′ that is described with reference to FIG. 14 or 20, and the controller 2200 may control a plurality of memory chips of the semiconductor memory device 2100 through the plurality of channels CH1 to CHk.

In FIG. 26, a plurality of semiconductor memory chips has been described as being coupled to each channel. However, it will be understood that the storage device 2000 may be modified such that a single semiconductor memory chip is coupled to each channel.

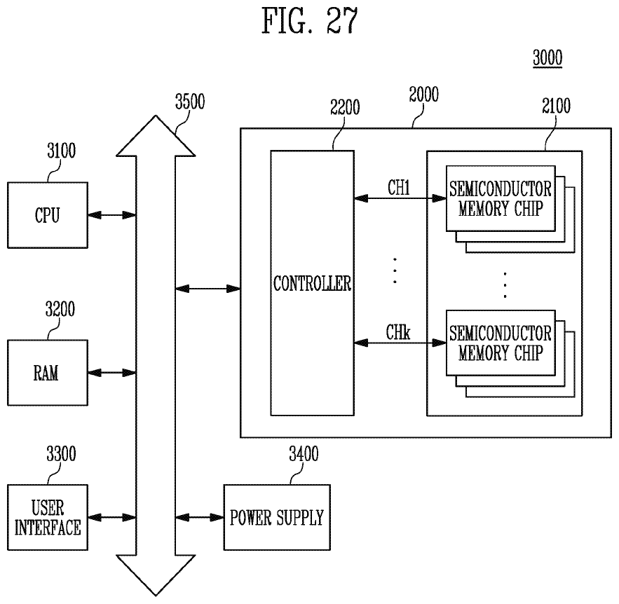

FIG. 27 is a block diagram, illustrating a computing system including the storage device described with reference to FIG. 26.

Referring to FIG. 27, a computing system 3000 may include a central processing unit (CPU) 3100, a RAM 3200, a user interface 3300, a power supply 3400, a system bus 3500, and a storage device 2000.

The storage device 2000 may be electrically coupled to the CPU 3100, the RAM 3200, the user interface 3300, and the power supply 3400 through the system bus 3500. Data provided through the user interface 3300 or processed by the CPU 3100 may be stored in the storage device 2000.

In FIG. 27, a semiconductor memory device 2100 is illustrated as being coupled to the system bus 3500 through the controller 2200. However, the semiconductor memory device 2100 may be directly coupled to the system bus 3500. Here, the function of the controller 2200 may be performed by the CPU 3100 and the RAM 3200.

In FIG. 27, the storage device 2000 described with reference to FIG. 26 is illustrated as being provided. However, the storage device 2000 may be replaced with the storage device 1000 described with reference to FIG. 25. In an embodiment, the computing system 3000 may include both the storage devices 1000 and 2000 described with reference to FIGS. 25 and 26.

The present disclosure may provide a semiconductor memory device with improved reliability and a controller to control the semiconductor memory device.

Although the embodiments of the present disclosure have been disclosed, those skilled in the art will appreciate that various modifications, additions and substitutions are possible, without departing from the scope and spirit of the present disclosure.

Therefore, the scope of the present disclosure must be defined by the appended claims and equivalents of the claims rather than by the description preceding them.

In the above-discussed embodiments, all steps may be selectively performed or skipped. In addition, the steps in each embodiment might not be always performed in regular order. Furthermore, the embodiments disclosed in the present specification and the drawings aim to help those with ordinary knowledge in this art more clearly understand the present disclosure rather than aiming to limit the bounds of the present disclosure. In other words, one of ordinary skill in the art to which the present disclosure belongs will be able to easily understand that various modifications are possible based on the technical scope of the present disclosure.

What is claimed is:

1. A storage device, comprising:
a semiconductor memory device including a first physical page that is coupled to a first word line and a second physical page that is coupled to a second word line; and
a controller configured to control a read operation of the semiconductor memory device,
wherein identical data is stored in each of the first physical page and in the second physical page, and
wherein the semiconductor memory device is configured to read the data by randomly selecting any one of the first physical page and the second physical page.

2. The storage device according to claim 1, wherein the controller generates a read command for reading the data and randomly generates a read address indicating any one of the first and second physical pages, and
wherein the controller controls the semiconductor memory device so that the read command and the read address are transferred to the semiconductor memory device before the data is read.

3. The storage device according to claim 2, wherein the controller comprises:
a read controller configured to generate a read control signal for reading the data;
a random value generator configured to generate a random value that corresponds to any one of the first word line and the second word line based on the read control signal;
an address generator configured to generate the read address based on the random value; and
a command generator configured to generate the read command based on the read control signal.

4. The storage device according to claim 1, wherein the controller generates a read command for reading the data and transfers the read command to the semiconductor memory device, and
wherein the semiconductor memory device randomly generates a read address indicating any one of the first and second physical pages in response to the read command, and reads the data based on the generated read address.

5. The storage device according to claim 4, wherein the semiconductor memory device comprises:
a memory cell array including the first physical page and the second physical page;
a control logic configured to receive the read command and then generate the read address and a read control signal;
an address decoder configured to receive the read address and then select any one of the first word line and the second word line; and
a read and write circuit configured to perform a read operation on a physical page that is coupled to the selected word line in response to the read control signal.

6. The storage device according to claim 5, wherein the control logic comprises a random address generator comprising:
a random value generator configured to generate a random value that corresponds to any one of the first word line and the second word line based on the read command; and
an address generator configured to generate the read address based on the random value.

7. The storage device according to claim 1, wherein the first physical page and the second physical page are included in a content-addressable memory area.

8. A storage device, comprising:
a semiconductor memory device including a plurality of page group;
the page group including a plurality of physical pages; and
a controller configured to control a read operation of the semiconductor memory device,
wherein identical data is stored in each of the plurality of physical pages in the page group, and
wherein the semiconductor memory device is configured to read the data by randomly selecting any one of the plurality of physical pages.

9. The storage device according to claim 8, wherein the controller generates a read command for reading the data and randomly generates a read address indicating any one of the plurality of physical pages, and
wherein controls the semiconductor memory device so that the read command and the read address are transferred to the semiconductor memory device and then the data is read.

10. The storage device according to claim 9, wherein the controller comprises:
a read controller configured to generate a read control signal for reading the data;
a random value generator configured to generate a random value that corresponds to any one of the plurality of physical pages based on the read control signal;
an address generator configured to generate the read address based on the random value; and
a command generator configured to generate the read command based on the read control signal.

11. The storage device according to claim 8, wherein the controller generates a read command for reading the data and transfers the read command to the semiconductor memory device, and
wherein the semiconductor memory device randomly generates a read address indicating any one of the plurality of physical pages in response to the read command, and reads the data based on the generated read address.

12. The storage device according to claim 11, wherein the semiconductor memory device comprises:
a memory cell array including the plurality of physical pages;
a control logic configured to receive the read command and then generate the read address and a read control signal;
an address decoder configured to receive the read address and then select any one of a plurality of word lines corresponding to the plurality of physical pages; and
a read and write circuit configured to perform a read operation on a physical page that is coupled to the selected word line in response to the read control signal.

13. The storage device according to claim 12, wherein the control logic comprises a random address generator comprising:
a random value generator configured to generate a random value that corresponds to any one of the plurality of physical pages based on the read command; and
an address generator configured to generate the read address based on the random value.

14. A method of operating a controller, the controller controlling a read operation of a semiconductor memory device in which identical page data is stored in each of a plurality of physical pages, the method comprising:
determining to read the page data that is stored in each of the plurality of physical pages;
randomly generating a read address that corresponds to any one of the plurality of physical pages in response to the determination;
generating a read command based on the generated read address; and
transferring the generated read address and read command to the semiconductor memory device.

15. The method according to claim 14, wherein the randomly generating of the read address that corresponds to any one of the plurality of physical pages comprises:
generating a random value with any one of a plurality of values in response to the determination; and
generating the read address based on the random value.

16. A method of operating a semiconductor memory device, the semiconductor memory device including a plurality of physical pages, each in which identical page data is stored, the method comprising:
receiving a read command for reading the page data;
randomly selecting any one of the plurality of physical pages in response to the receiving of the read command; and
performing a read operation on the selected physical page.

17. The method of claim 16, wherein the randomly selecting of any one of the plurality of physical pages in response to the receiving of the read command comprises:
generating a random value with any one of a plurality of values; and
generating, based on the random value, a read address corresponding to any one of the plurality of physical pages.

18. The method according to claim 17, further comprising:
transferring the data, read as a result of the read operation, to a controller.
